(19) United States
(12) Patent Application Publication
(10) Pub. No.: US 2006/0192197 A1
(43) Pub. Date: Aug. 31, 2006

(54) Organic thin film transistor

(75) Inventor: Akio Koganei, TOKYO (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/551,092

(22) PCT Filed: Mar. 26, 2004
(86) PCT No.: PCT/JP04/04350

§ 371 Date: Sep. 27, 2005

(30) Foreign Application Priority Data
Mar. 31, 2003 (JP) 2003-096208

(51) Int. Cl. H01L 29/08

(52) U.S. Cl. 257/40

(57) ABSTRACT

An organic thin film transistor utilizing an organic semiconductor film is composed of a first substrate, a gate electrode, a gate insulation film, an organic semiconductor film, a source electrode, a drain electrode, a protective film and a second substrate, and produced by forming a gate electrode, a gate insulation film, an organic semiconductor film, a source electrode, and a drain electrode on a first substrate, forming a protective film on a second substrate, and superposing a surface, bearing the organic semiconductor film, of the first substrate upon a surface, bearing the protective film, of the second substrate.

### FIELD OF THE INVENTION

The present invention relates to a thin film transistor utilizing an organic semiconductor material and a producing method therefor, and more particularly to a method for producing a protective film for an organic semiconductor layer.

### BACKGROUND OF THE INVENTION

Development of a thin film transistor employing an organic semiconductor material (hereinafter called organic thin film transistor) is being accelerated in recent years. It is anticipated that the use of an organic material allows a lower temperature to be achieved in the process, thus enabling transistors to be formed in a large area with a lower cost. Applications are expected in a driving circuit for a thin display panel or an electronic paper, a radio frequency identification (RF-ID) tag, an IC card, etc. There are also known certain technical reviews (C. D. Dimitrakopoulos et al., “Organic Thin Film Transistors for Large Area Electronics,” Advanced Material, 14, No. 2, p. 99-177(2002)).

An example of the structure of an organic thin film transistor is shown in FIG. 3, in which shown are a substrate 301, a gate electrode 302 formed by a conductive film, a gate insulation film 303, an organic semiconductor film 304, a source electrode 305, and a drain electrode 306.

In FIG. 3, the substrate 301 may be formed, for example, by a glass-epoxy resin. In such case, the gate electrode 302 is formed by patterning a conductive film into the shape of the gate electrode and then subjected to a flattening process by polishing. An organic thin film transistor is formed by forming thereon a gate insulation film, an organic semiconductor film, a source electrode and a drain electrode.

For operating such organic thin film transistor, a voltage exceeding a threshold value Vth is applied to the gate electrode in a state that the source electrode is grounded and a drain voltage Vdd is applied to the drain electrode. In this state, a conductivity of the organic semiconductor film changes by an electric field effect in the vicinity of the gate electrode, whereby a current flows between the source electrode and the drain electrode. The current between the source electrode and the drain electrode can be turned on and off as in a switch by the gate voltage.

The organic semiconductor material employed in the organic thin film transistor has a susceptibility to light, water, oxygen, etc. This is presumably due to a change in the conductivity, by an increase in hole trapping sites by oxygen doping, and by a change of chemical bonding structure by a light irradiation. In particular, few N-type semiconductor materials are stable in the air. Consequently, demands for a technology of providing a protective film for shielding the organic semiconductor film from the light and/or sealing the organic semiconductor film is very strong.

Various sealing and light-shielding technologies are already proposed in an organic EL element which has been put into practice. As a sealing technology, a stress relaxing layer having a sealing property is proposed (for example, Japanese Patent Application Laid-open No. H08-124677 (pages 9 to 10, FIG. 1)). Also as a light shielding technology, a structure of shielding a thin film transistor, for driving an organic EL element, from light (for example, Japanese Patent Application Laid-open No. 2002-108250 (pages 6 to 7, FIG. 1)). Also in relation to the organic thin film transistor, there is proposed an in-situ formation of a protective film after forming an organic semiconductor film by evaporation (for example, Japanese Patent Application Laid-open No. 2002-314093).

On the other hand, as an inexpensive sealing technology, a laminating technology is already known. Lamination means superposing layers, and a laminated film for food wrapping is formed by laminating two or more films of different materials (for example, nylon and polyethylene), and achieves sealing by thermal fusion. Various information are available on the laminated film (for example, “Types of films and laminates” (online), Kono Hozai Kikaku Co. (searched on Dec. 26, 2002), internet <URL: http://plaza27.mbn.or.jp/˜konohozai/fukuro˜rami1.>).

Also Japanese Patent Application Laid-open No. 2001-230421 proposes that a first substrate and a second substrate are formed to make up a mutually connected structure, forming a part of a thin film transistor on the first substrate and a remaining part on the second substrate and laminating these two substrates, thereby forming an integrated circuit device including a thin film transistor (TFT).

The sealing technology and the light shielding technology, already known and derived from the organic EL element, can provide a certain effect also in the organic thin film transistor. However, the aforementioned sealing technology is accompanied by an operation difficult in handling because a viscous stress relaxing layer are utilized, or involves a high apparatus cost because a vacuum process employing ammonia is utilized, and is not sufficient for producing an inexpensive organic thin film transistor utilizing a plastic substrate. It is also insufficient to realize an inexpensive flexible structure utilizing a plastic substrate.

It is therefore desired, for realizing an inexpensive process, to apply a technology such as lamination for forming a protective film, but a simple lamination is associated with such a drawback that an excessively high stress is locally applied to the organic semiconductor film by a pressing operation under heating.

Particularly in a case where the source electrode and the drain electrode are formed, instead of masked evaporation, by a printing technology such as offset printing or screen printing, the resulting electrodes have a large film thickness. Thus, because of a large gap between a portion of the electrode and a portion not having the electrode, an excessive stress is applied to the organic semiconductor film. Therefore, there is a drawback in that many of the organic thin film transistors are broken or impaired in performance.

### DISCLOSURE OF THE INVENTION

In consideration of the foregoing, a first object of the present invention is to construct a process for forming a protective film, which causes no destruction and provides a high productivity in producing an inexpensive organic thin film transistor utilizing a plastic substrate.

A second object of the present invention is to provide a process for forming a protective film having high sealing properties and excellent light shielding properties.

A third object of the present invention is to provide an inexpensive semiconductor device utilizing a plurality of transistors capable of providing stable operation characteristics.

As a result of intensive investigations, it is concluded that the following means are effective in attaining the aforementioned objectives.

The present invention provides an organic thin film transistor characterized by comprising a first substrate, a gate electrode, a gate insulation film, an organic semiconductor film, a source electrode, a drain electrode, a protective film and a second substrate. It is preferred that the protective film is a pliable substance or at least part of the protective film comprises a pliable substance having a consistency within a range from 200 to 700.

It is preferred that the protective film comprises a pliable substance and an insulation film. It is also preferred that the protective film comprises a pliable substance and a light-shielding film.

It is also preferred that the protective film is formed from a mixture containing a pliable substance and a hygroscopic material.

Preferably the pliable substance is a vacuum grease.

Also preferably the hygroscopic material contains calcium carbonate.

In addition, a method of the present invention for producing an organic thin film transistor is characterized in that the organic thin film transistor comprises a first substrate, a gate electrode, a gate insulation film, an organic semiconductor film, a source electrode, a drain electrode, a protective film and a second substrate, and characterized by forming a gate electrode, a gate insulation film, an organic semiconductor film, a source electrode, and a drain electrode on a first substrate, and forming a protective film on a second substrate, and superposing a surface, bearing the organic semiconductor film, of the first substrate upon a surface, bearing the protective film of the second substrate.

It is preferred that the protective film comprises a pliable substance having a consistency within a range from 200 to 700.

It is also preferred that the source electrode and/or the drain electrode is formed by a printing technology.

The present invention also provides an apparatus for producing an organic thin film transistor utilizing an organic semiconductor film, which superposes the protective film by the aforementioned producing method, the apparatus being characterized by successively executing a step for forming the organic semiconductor film and a step for superposing the protective film in the same apparatus.

According to the present invention, an organic thin film transistor can be realized in an inexpensively sealable structure by adopting, for the organic thin film transistor, a configuration including a first substrate, a gate electrode, a gate insulation film, an organic semiconductor film, a source electrode, a drain electrode, a protective film and a second substrate. Also a protective film can be formed without destruction of the device by a method of superposing a second substrate bearing a protective film on a first substrate bearing an organic semiconductor film.

Also as a protective film having a high sealing property and an excellent light shielding property can be formed, it is rendered possible to provide an inexpensive semiconductor device which utilizes a plurality of transistors and is capable of providing stable operation characteristics.

Other features and advantages of the present invention will be apparent from the following description taken in conjunction with the accompanying drawings, in which like reference characters designate the same or similar parts through the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic view showing a configuration of an organic thin film transistor of the present invention;

FIG. 2 is a schematic view showing a second substrate and a protective film of the present invention;

FIG. 3 is a schematic view showing the structure of an organic thin film transistor of a prior technology;

FIG. 4 is a schematic view showing a process for producing an organic thin film transistor of the present invention;

FIG. 5 is a schematic view showing a process for producing an organic thin film transistor of the present invention;

FIG. 6 is a schematic view showing a process for producing an organic thin film transistor of the present invention;

FIG. 7 is a schematic view showing a process for producing an organic thin film transistor of the present invention;

FIG. 8 is a schematic view showing a process for producing an organic thin film transistor of the present invention;

FIG. 9 is a schematic view showing a process for producing an organic thin film transistor of the present invention;

FIG. 10 is a chart showing a fluctuation in a drain current Id in Example 1;

FIG. 11 is a chart showing a fluctuation in a drain current Id in Comparative Example 1;

FIG. 12 is a chart showing a change of a mobility over time in one element in each of Example 1 and Comparative Example 1;

FIG. 13 is a schematic view showing a configuration of an organic thin film transistor in Example 2 of the present invention;

FIG. 14 is a chart showing a fluctuation in a drain current Id in Example 2;

FIG. 15 is a chart showing a fluctuation in a drain current Id in Comparative Example 2;

FIG. 16 is a chart showing a change of a mobility over time in one element in each of Example 2 and Comparative Example 2;

FIG. 17 is a schematic view showing a configuration of an organic thin film transistor in Example 3 of the present invention;

FIG. 18 is a chart showing a fluctuation in a drain current Id in Example 3;

FIG. 19 is a chart showing a fluctuation in a drain current Id in Comparative Example 3;

FIG. 20 is a chart showing a change of a mobility over time in one element in each of Example 3 and Comparative Example 3;

FIG. 21 is a schematic view showing a configuration of an organic thin film transistor in Example 4 of the present invention;

FIG. 22 is a chart showing a fluctuation in a drain current Id in Example 4;

FIG. 23 is a chart showing a fluctuation in a drain current Id in Comparative Example 4;

FIG. 24 is a chart showing a change of a mobility over time in one element in each of Example 4 and Comparative Example 4;

FIG. 25 is a schematic view showing a configuration of an organic thin film transistor in Example 5 of the present invention;

FIG. 26 is a chart showing a fluctuation in a drain current Id in Example 5;

FIG. 27 is a chart showing a fluctuation in a drain current Id in Comparative Example 5;

FIG. 28 is a chart showing a change of a mobility over time in one element in each of Example 5 and Comparative Example 5;

FIG. 29 is a schematic view showing an apparatus for producing an organic thin film transistor in Example 6 of the present invention;

FIG. 30 is a chart showing a fluctuation in a drain current Id in Example 7;

FIG. 31 is a chart showing a fluctuation in a drain current Id in Comparative Example 6; and

FIG. 32 is a chart showing a change of a mobility over time in one element in each of Example 7 and Comparative Example 6.

### BEST MODE FOR CARRYING OUT THE INVENTION

Preferred embodiments of the present invention will now be described below in detail in accordance with the accompanying drawings.

As a result of intensive investigations for a protective film forming process providing a high productivity in producing an inexpensive organic thin film transistor utilizing a plastic substrate, it has been identified that the formation of a protective film by superposing a second substrate as in lamination is effective in realizing an inexpensive process, and that, in superposing the second substrate, an excessive stress is applied locally to the organic semiconductor film by pressing operation for obtaining a close contact. In order to overcome such a situation, the use of a pliable substance as the protective film has been found, and based on this finding, the present invention has been made.

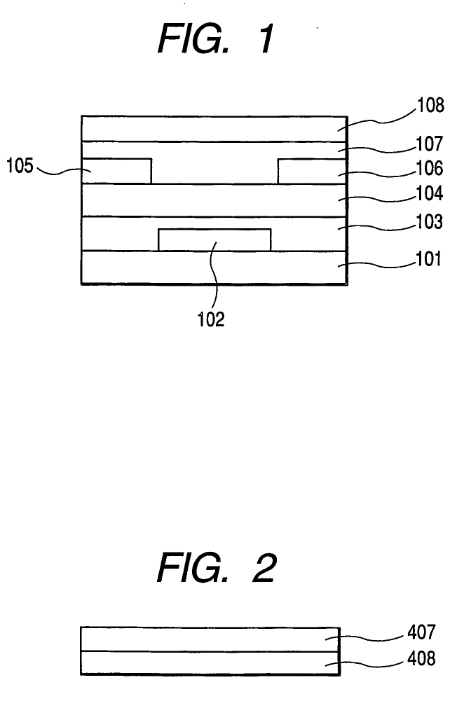

An example of the configuration of an organic thin film transistor of the present invention is shown in FIG. 1, in which shown are a first substrate 101, a gate electrode 102 formed by a conductive film, a gate insulation film 103, an organic semiconductor film 104, a source electrode 105, a drain electrode 106, a protective film 107 and a second substrate 108.

In the preparation of the organic thin film transistor of the present invention, a laminated structure up to the source electrode 105 and the drain electrode 106 is formed on the first substrate 101, while the protective film 107 is formed on the second substrate 108. The organic thin film transistor of the present invention can be completed by superposition in such a manner that an exposed surface of the organic semiconductor film 104 of the first substrate 101 is brought into contact with the protective film 107 on the second substrate 108.

The protective film 107 provided on the second substrate 108 is composed of a pliable substance and is deformed, upon contacting the organic semiconductor film of the first substrate, according to the shape on the first substrate. Therefore, the pressure in the superposing operation is relaxed, and the protective film can be formed without applying any excessive stress to the organic thin film transistor.

Also by regulating conditions under which the protective film is formed on the second substrate, it is possible to prevent the protective film from flowing and sticking to unnecessary portions. Therefore, handling properties in the device preparation are significantly improved, thereby improving the productivity.

As the pliable substrate used for the protective film, there may be used an inert insulating material which does not chemically react with the organic semiconductor film. There is also preferred a substance showing little gas release and having a sealing effect to water, air and oxygen. A grease, a varnish or a gel can be used for this purpose. More specifically, the grease can be, for example, a silicone-type grease, a fluorinated grease (such as PTFE grease employing Teflon (trade name) as a consistency increasing agent), or a hydrocarbon-type grease (such as Apiezon grease), which can be employed as a vacuum grease. Also the gel can be, More specifically, the gel may be gelatin, a cellulose or an amide.

A hardness of the grease is represented by a cone consistency (JIS K2220.5.3) and is defined by a penetration depth of a defined cone into the grease. Grease is constituted by a base material, a consistency increasing agent and an additive, and, in a case where the consistency increasing agent and the additive are formed by solid particles, smaller particles adaptable to small irregularities are preferable in not applying an excessive stress to the organic semiconductor film. As the grease is harder, the consistency becomes smaller and the consistency number increases. The grease employed in the present invention preferably has a consistency of 200 to 450, more preferably 250 to 350.

The protective film can also be a laminate formed from plural materials. For example, there may be employed a combination of an inorganic or organic insulation film and the aforementioned pliable substance. The inorganic insulation film can be formed by, for example, an oxide such as SiO₂, Al₂O₃ or Ta₂O₅, or a nitride such as Si₃N₄ showing a low oxygen permeability. Also the organic insulation film can be formed by, for example, an insulating organic polymer such as polyvinylphenol (PVP), polymethyl methacrylate (PMMA) or polyethylene.

The protective film can also be a mixture of plural materials. For example, a mixture of a hygroscopic material and the aforementioned pliable substance may be employed. The hygroscopic material can be, for example, calcium carbonate, synthetic zeolite, barium oxide or silica gel.

The protective film may also include a layer of a material of a high light-shielding property or contain such material mixed therein. When the material of a high light-shielding property is conductive, it may be provided on the side of the second substrate.

The first substrate of the present invention may be selected from an inorganic material such as a silicon wafer or glass, and an organic material such as polyethylene terephthalate, polycarbonate, polyethylene, polystyrene, polyimide, polyvinyl acetate, polyvinyl chloride or polyvinylidene chloride. Such substrate can be suitably selected according to the application, in consideration of properties required for the substrate such as a flatness, a strength, a heat resistance, a thermal expansion coefficient, a cost, etc.

For the second substrate of the present invention, there can be utilized various polymer materials, such as nylon, polyester, polycarbonate, polyethylene terephthalate, ethylene-vinyl acetate copolymer (PVA), biaxially drawn polypropylene, high-density polyethylene or low-density polyethylene. It is also possible to employ a material coated with vinylidene chloride for improving oxygen barrier properties or a material evaporated with aluminum in order to improve light shielding properties. In such a case, a surface coming into contact with the organic semiconductor film may be formed of an insulating material.

In the second substrate of the present invention, it is important, in order to regulate an adhesive force to the protective film, to provide a surface coming into contact with the protective film with an affinity for the protective film, and a surface not coming into contact with the protective film with a repellency to the protective film. Means for such regulation includes various surface treatments such as a plasma treatment, an ozone treatment and a UV treatment, and provision of a new functionality such as an adhesive layer. Details of these technologies will be easily understandable to those skilled in the related art.

In the present invention, the second substrate and the protective film are distinguished by the fact that the second substrate can singly retain its shape as a substrate, while the protective film cannot retain its shape in the absence of the substrate. In other terms, the second substrate and the protective film are different in the thickness, and a member thicker than a boundary thickness of about 50 μm is defined as the second substrate while a member thinner than 50 μm is defined as the protective film, though such boundary thickness is variable depending on the constituent material.

The first substrate of the present invention may be sandwiched between two second substrates (FIG. 11). In such a case, a thermal fusion, which is generally known as lamination, may be executed.

The organic semiconductor film of the present invention can be suitably selected from an oligomer having π-conjugated electrons such as pentacene, tetracene, or anthracene, and an organic semiconductor polymer such as polythiophene, polyacene, polyacetylene or polyaniline.

The gate insulation film in the present invention can be, for example, formed by an inorganic oxide such as SiO₂, Al₂O₃ or Ta₂O₅, or a nitride such as Si₃N₄. The gate insulation film is preferably formed from a material of a high dielectric constant, in order to reduce a resistance in an on-state and to increase a drain current. There can also be employed an insulating organic polymer such as polyvinylphenol (PVP), polymethyl methacrylate (PMMA) or polyethylene.

For the gate electrode, the source electrode and the drain electrode of the present invention, a precious metal such as gold, silver or platinum, or a material of a high conductivity such as copper or aluminum may be employed. Also these electrodes may be formed from a conductive polymer.

The organic thin film transistor is known in a top electrode structure (TE) in which a source electrode and a drain electrode are formed on an organic semiconductor film relative to a substrate, and a bottom electrode structure (BE) in which a source electrode and a drain electrode are formed on a gate insulation film and then an organic semiconductor film is formed thereon. The TE structure, lacking the source electrode and the drain electrode on the gate insulation film, allows easy preparation of an organic semiconductor film of a high quality, whereby the mobility tends to be higher than in the BE structure. On the other hand, the TE structure is associated with a drawback such that the manufacturing process becomes complex because the connection with the electrode structure on the lower side is required to be made by limiting a film forming area of the organic semiconductor film. The protective film forming process of the present invention is applicable to both the TE structure and the BE structure.

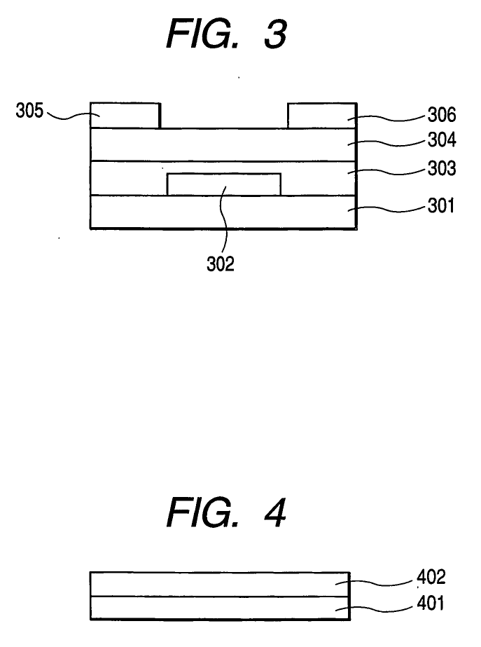

The operation sequence of the organic thin film transistor of the present invention is the same as that of the prior structure shown in FIG. 3. A voltage exceeding a threshold voltage Vth is applied to the gate electrode in a state in which the source electrode is grounded and a voltage Vdd is applied to the drain electrode. In this state, the conductivity of the organic semiconductor film varies with an electric field from the gate electrode, whereby a current flows between the source electrode and the drain electrode. The current between the source electrode and the drain electrode can be turned on and off, as in a switch, by the gate voltage.

### EXAMPLES

In the following, the present invention will be explained below in more details by giving examples.

### Example 1

FIGS. 4 to 9 are schematic views showing a method for producing the organic thin film transistor of the present invention. In FIG. 4, 401 denotes a substrate and 402, a conductor film. The members 401 and 402 are commercially distributed as a printed circuit board in an integrated form in a combination of, for example, a glass-epoxy resin substrate and a copper foil. In the present example, there was employed a board (model: FR-4, manufactured by Hitachi Chemical Co.) with a substrate of a thickness of 0.2 mm and a copper foil constituting the conductor film of a thickness of 35 μm. The board is often in a form in which conductor films are provided on both sides, but the explanation is omitted because it is unnecessary for the description of the present invention.

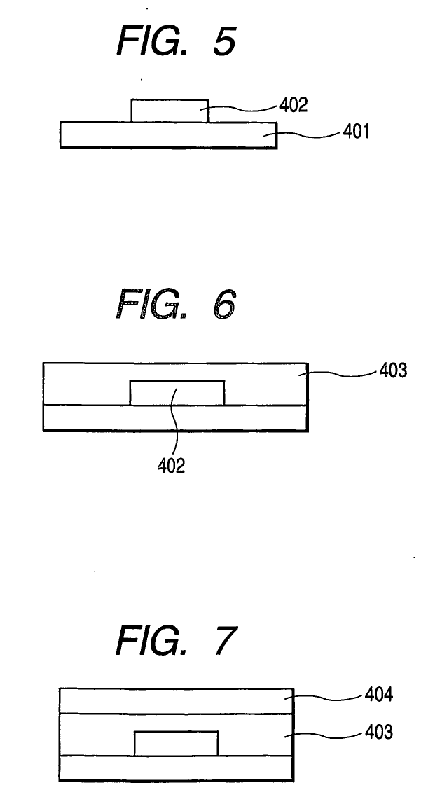

Then the conductor film is subjected to a patterning and formed into a desired gate shape. The patterning can be carried out by using a mask formation by a lithographic technology utilizing a dry film, and a shape transfer by wet etching of the conductor film. FIG. 5 shows a state after working into a wiring form, wherein 402 indicates a conductor film constituting the gate electrode. After the wet etching, this conductor film portion is polished with CMP for adjusting the surface to a roughness required for executing the present invention.

FIG. 6 shows a state in which a gate insulation film 403 is formed on the conductor film 402 for constituting the gate electrode. The gate insulation film 403 was formed by magnetron sputtering. A film forming area was defined by a shadow mask. The film was formed from Al₂O₃ and had a thickness of 250 nm.

FIG. 7 shows a state in which an organic semiconductor film 404 is formed on the gate insulation film 403. The organic semiconductor film 404 was formed by evaporation. A film forming area was defined by a shadow mask. The film was formed from pentacene and had a thickness of 150 nm.

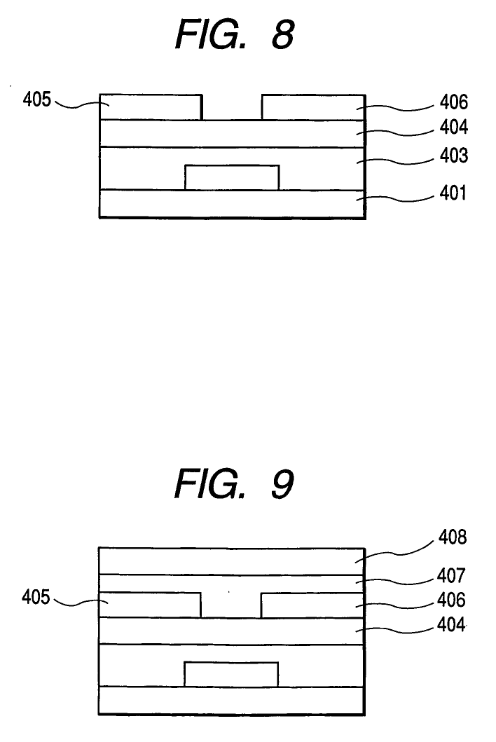

FIG. 8 shows a state in which a source electrode 405 and a drain electrode 406 are formed in contact with the organic semiconductor film 404. The source electrode 405 and the drain electrode 406 were formed by evaporation. A film forming area was defined by a shadow mask. The film was formed from Au and had a thickness of 100 nm.

FIG. 9 shows a state after a protective film 407 and a second substrate 408 are superposed so as to cover the organic semiconductor film 404, the source electrode 405 and the drain electrode 406. The protective film 407 was constituted of silicone vacuum grease manufactured by Shin-etsu Silicone Co., having a thickness of 60 μm prior to superposition, and the second substrate 408 was constituted of polyethylene of a thickness of 150 μm. The second substrate 408 provided with the protective film 407, prior to superposition, has a flat shape in which the protective film 407 lies parallel to the second substrate 408. (FIG. 2). After the superposition, however, the protective film 407 is deformed as shown in FIG. 9 and covers the entire surface, following the profile formed by the organic semiconductor film 404, the source electrode 405 and the drain electrode 406. Therefore, as the pressure applied at the superposition is not concentrated in a particular electrode portion, the organic semiconductor film receives only a low stress. Consequently, the protective film can be formed without impairing the characteristics of the device or causing its destruction.

Then, the substrate subjected up to the polishing step is cut into a card size (86×54 mm). This substrate was subjected to subsequent steps to complete a transistor element. After the completion, the DC characteristics of the transistor element were measured with a parameter analyzer (HP4155B). In a pattern employed for testing, 120 transistors of a same size were arranged on a substrate thus cut. As a result, satisfactory characteristics with a low gate leakage and a low fluctuation in Vth were obtained.

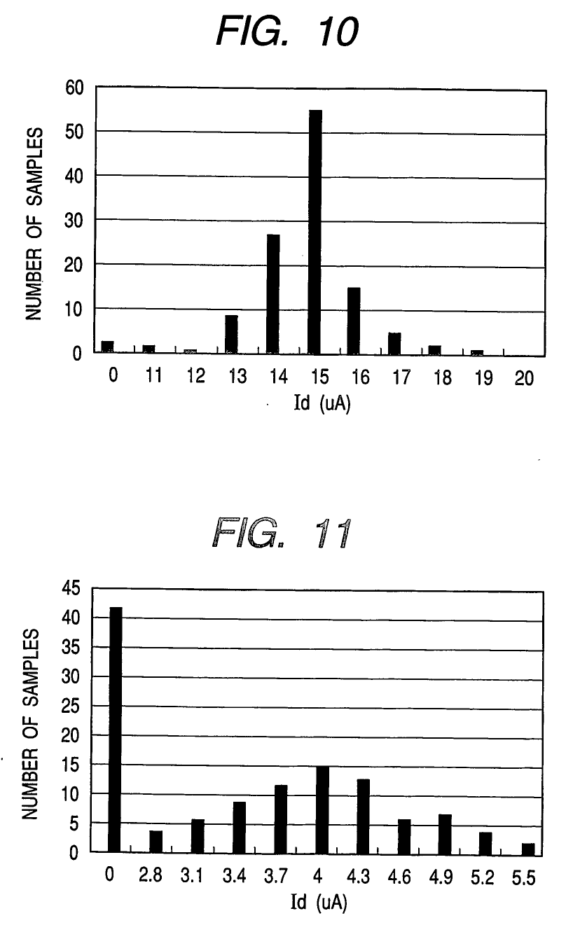

FIG. 10 is a chart showing a fluctuation in the drain current Id where a source voltage, a drain voltage and a gate voltage respectively of 0 V, −20 V and −20 V are applied to an element of a gate length of 80 μm and a gate width of 5 mm. The chart is in a form close to the normal distribution curve with the half-width being narrow. Also the elements showing Id=0 by destruction were satisfactorily less than 10.

### Comparative Example 1

On the other hand, as a comparative example, an element was prepared through all the same steps except that the protective film 407 was not provided, and the DC characteristics of the transistor element were evaluated. As a result, many elements present on one substrate were broken, and also the transistor characteristics showed significant fluctuation. FIG. 11 is a chart showing a fluctuation of the drain current Id measured in the same manner as in Example 1 shown in FIG. 10. While the element size is the same as in Example, the drain current is about ¼. Also the half-width is wider, indicating a larger fluctuation. In addition, it can be observed that nearly half of the elements showed Id=0 due to the element destruction.

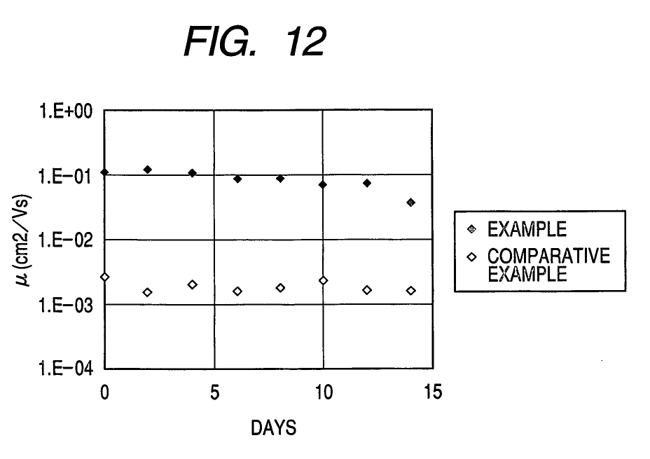

FIG. 12 is a chart showing a change over time of the mobility measured for one element in each of Example 1 and Comparative Example 1. The storage environment is the air of 25° C. and 45%. The element of the Comparative Example showed a mobility lower by about one digit than the element of the Example. Based on the fact that the satisfactory transistor characteristics were obtained, it was confirmed that the organic semiconductor film was not exposed to the air and the sealing was effective.

### Example 2

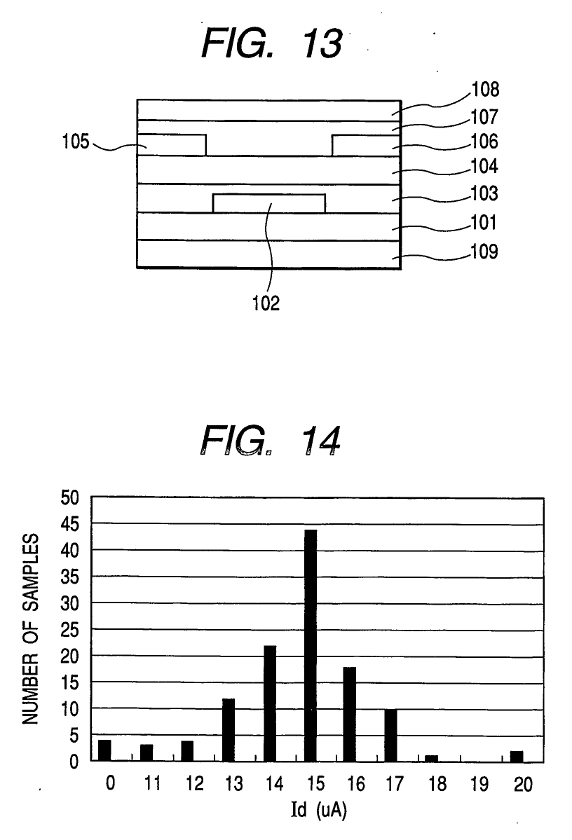

An organic thin film transistor was prepared with the same configuration as in Example 1 except that the first substrate 101 was sandwiched between, and laminated with, two second substrates 108, 109, and evaluation was made on the transistor characteristics after superposition in the presence and absence of the protective film. FIG. 13 shows a schematic cross-sectional view. The second substrate 108 or 109 was formed from a polyethylene-polyester-EVA film of a thickness of 150 μm. Vacuum grease was applied with a bar coater in a thickness of 60 μm and was heated in a clean oven at 70° C. to elevate an adhesive force to the second substrate. A grease-free area was provided in the periphery to enable heat sealing to be effected.

A thin film transistor element was prepared in the same manner as in Example 1. The lamination was executed with a commercially available laminator (Asmix, manufactured by Aska Co.). Static characteristics were measured with a semiconductor parameter analyzer.

FIG. 14 is a chart showing a fluctuation in the drain current Id in a state that a source voltage, a drain voltage and a gate voltage respectively of 0 V, −20 V and −20 V were applied to an element of a gate length of 80 μm and a gate width of 5 mm. The chart shows a form close to the normal distribution curve with the half-width being narrow. Also the elements showing Id=0 by destruction were satisfactorily less than 10.

### Comparative Example 2

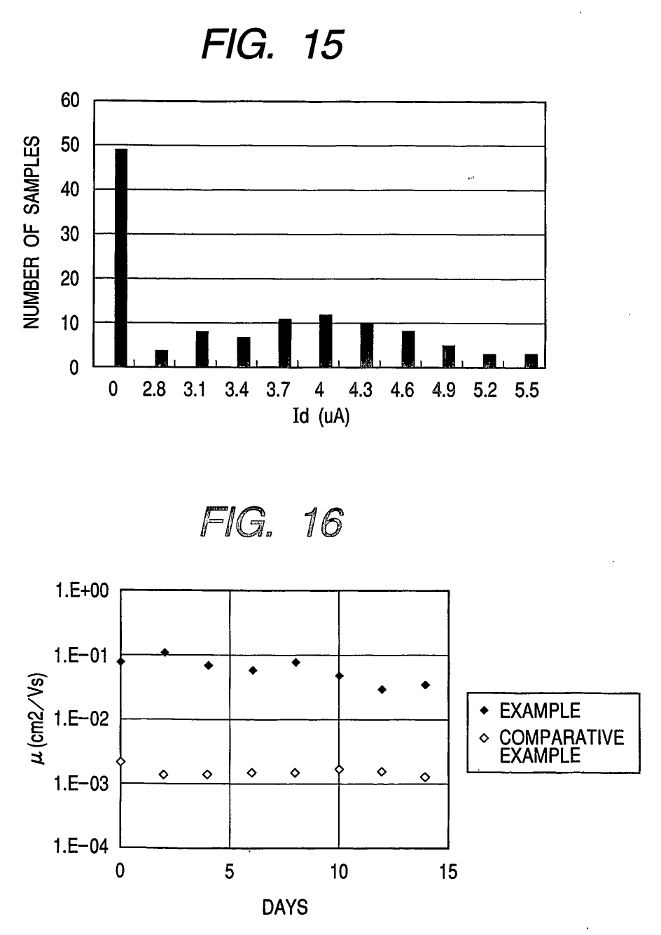

On the other hand, as a comparative example, an element was prepared through all the same steps except that the protective film was not provided, and the DC characteristics of the transistor element were evaluated. As a result, many elements present on one substrate were broken, and the transistor characteristics showed significant fluctuation. FIG. 15 is a chart showing a fluctuation of the drain current Id measured in the same manner as in the Example shown in FIG. 14. While the element size is the same as in Example, the drain current is about ¼. Also the half-width is wider, indicating a larger fluctuation. In addition, it can be observed that nearly half of the elements shows Id=0 due to the element destruction.

FIG. 16 is a chart showing a change over time of the mobility measured for one element in each of the Example and the Comparative Example. The storage environment was the air of 25° C. and 45%. The element of the Comparative Example showed a mobility lower by about one digit than the element of the Example. Based on the fact that the satisfactory transistor characteristics were obtained, it was confirmed that the organic semiconductor film was not exposed to the air and the sealing was effective.

### Example 3

An organic thin film transistor was prepared with the same configuration as in Example 1 except that a laminate formed from a combination of an insulation film and vacuum grease constituting the aforementioned pliable substance was employed as the protective film, evaluation was made on the transistor characteristics after superposition in the presence and absence of the protective film. The insulation film was formed from an inorganic oxide SiO₂ of a thickness of 1 μm. The second substrate was formed from a polyethylene-polyester-EVA film of a thickness of 150 μm. On the second substrate, an SiO₂ film was formed by means of reactive sputtering in a magnetron sputtering apparatus. An oxygen mixing ratio of 5% to Ar and a discharge pressure of 0.4 Pa were employed.

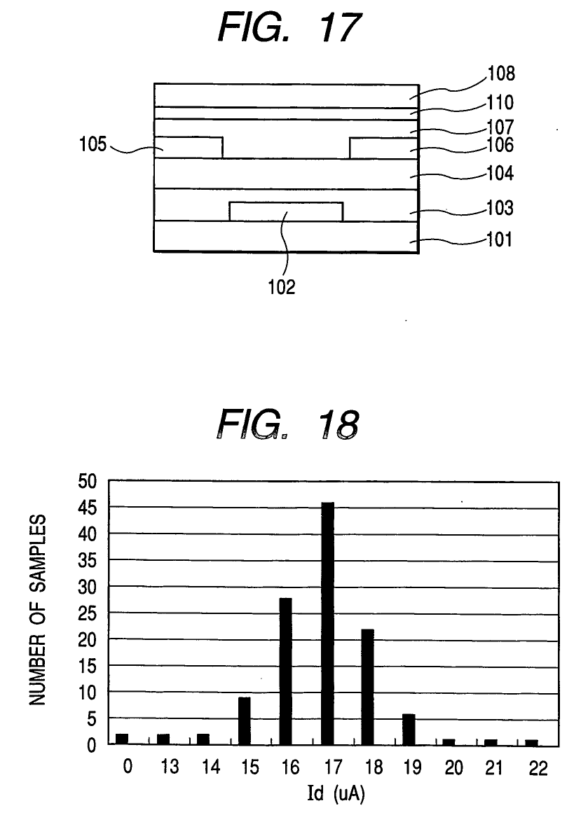

A thin film transistor element was prepared in the same manner as in Example 1. As shown in a schematic cross-sectional view in FIG. 12, and in contrast to Example 1 shown in FIG. 1, a laminated structure composed of an oxygen barrier layer of SiO₂ (insulation film 110 in FIG. 17) and vacuum grease (107 in FIG. 17) was employed. Static characteristics were measured with a semiconductor parameter analyzer.

FIG. 18 is a chart showing a fluctuation in the drain current Id in a state that a source voltage, a drain voltage and a gate voltage respectively of 0 V, −20 V and −20 V are applied to an element of a gate length of 80 μm and a gate width of 5 mm. The chart shows a form close to the normal distribution curve with the half-width being narrow. Also the elements showing Id=0 by destruction were satisfactorily less than 10.

### Comparative Example 3

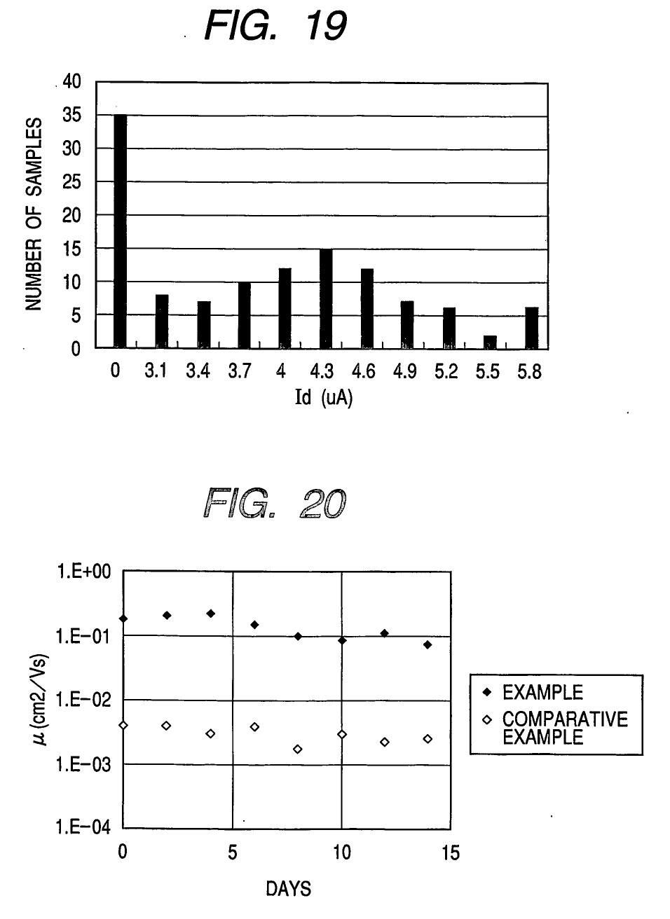

On the other hand, as a comparative example, an element was prepared through all the same steps except that the protective film was not provided, and the DC characteristics of the transistor element were evaluated. As a result, many elements present on one substrate were broken, and also the transistor characteristics showed significant fluctuation. FIG. 19 is a chart showing a fluctuation of the drain current Id measured in the same manner as in Example 3 shown in FIG. 18. While the element size is the same as in the Example, the drain current is about ¼. In addition, the half-width is wider, indicating a larger fluctuation. Also it can be observed that nearly half of the elements shows Id=0 due to the element destruction.

FIG. 20 is a chart showing a change over time of the mobility measured for one element in each of the Example and Comparative Example. The storage environment is the air of 25° C. and 45%. The element of the Comparative Example showed a mobility lower by about one digit than the element of the Example. Based on the fact that the satisfactory transistor characteristics were obtained, it was confirmed that the organic semiconductor film was not exposed to the air and the sealing was effective.

### Example 4

An organic thin film transistor was prepared with the same configuration as in Example 1 except that a mixture of plural different materials was employed as the protective film, and evaluation was made on the transistor characteristics after superposition in the presence and absence of the protective film. The mixture was composed of calcium carbonate which is a hygroscopic material, and vacuum grease which is the aforementioned pliable substance. Calcium carbonate was mixed by 10 wt. % and agitated sufficiently in vacuum grease produced by Shin-etsu Silicone Co., and the mixture was applied with a bar coater in a thickness of 60 μm and was heated at 70° C. in a nitrogen atmosphere to elevate an adhesive force to the second substrate.

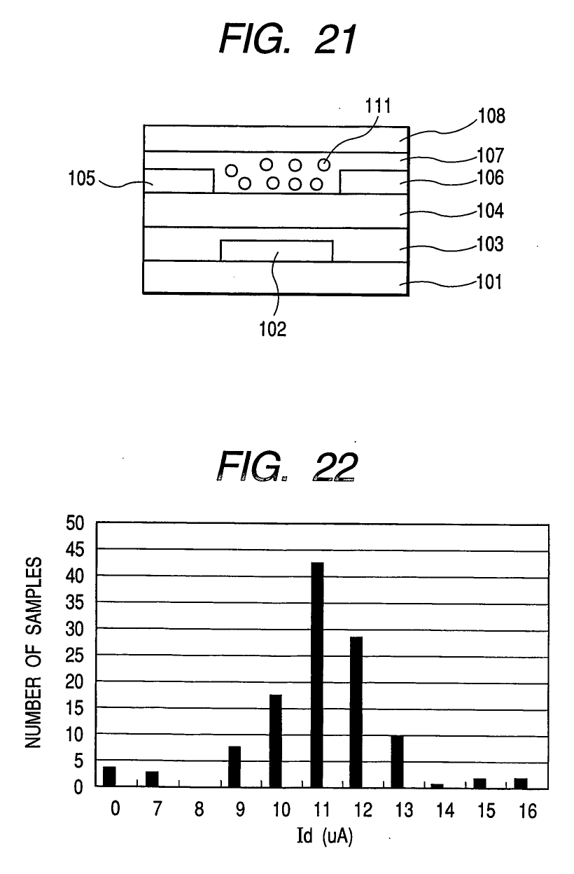

A thin film transistor element was prepared in the same manner as in Example 1. As shown in a schematic cross-sectional view in FIG. 21, and in contrast to Example 1 shown in FIG. 1, calcium carbonate constituting the hygroscopic material (111 in FIG. 21) was added to vacuum grease which is the pliable substance. Static characteristics were measured with a semiconductor parameter analyzer. FIG. 22 is a chart showing a fluctuation in the drain current Id in a state that a source voltage, a drain voltage and a gate voltage respectively of 0 V, −20 V and −20 V were applied to an element of a gate length of 80 μm and a gate width of 5 mm. The chart shows a form close to the normal distribution curve with the half-width being narrow. Also the elements showing Id=0 by destruction were satisfactorily less than 10.

### Comparative Example 4

On the other hand, as a comparative example, an element was prepared through all the same steps except that the protective film was not provided, and the DC characteristics of the transistor element were evaluated. As a result, many elements present on a same substrate were broken, and also the transistor characteristics showed significant fluctuation.

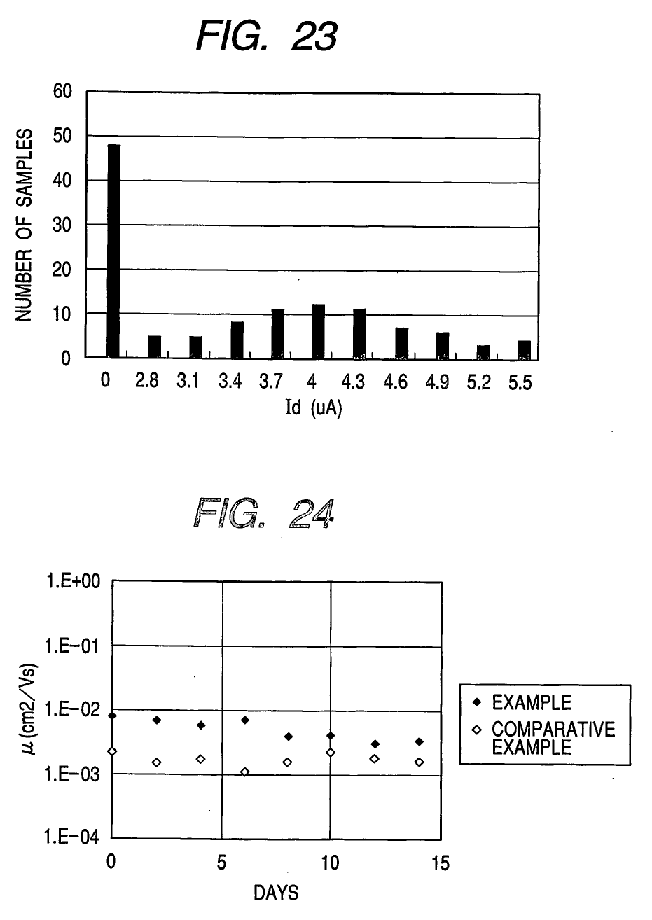

FIG. 23 is a chart showing a fluctuation of the drain current Id in a measurement same as that of Example shown in FIG. 22. Despite that the element size is same as in Example, the drain current is about ¼. Also the half-width is wider, indicating a larger fluctuation. Also it can be observed that about a half of the element shows Id=0 by destruction of the element.

FIG. 24 is a chart showing a change over time of the mobility measured for one element in each of Example 4 and Comparative Example 4. The storage environment is the air of 25° C. and 45%. The element of the Comparative Example showed a mobility lower by about one digit than the element of the Example. Based on the fact that the satisfactory transistor characteristics were obtained, it was confirmed that the organic semiconductor film was not exposed to the air and the sealing was effective.

### Example 5

An organic thin film transistor was prepared with a configuration same as in Example 1 except that an Al film was formed on the second substrate for increasing the light shielding property, and evaluation was made on the transistor characteristics after superposition in the presence and absence of the protective film. The second substrate was composed of a polyethylene-polyester-EVA film with a thickness of 150 μm. On the surface, on which the protective film is not formed, of the second substrate, an Al film of 0.3 μm was formed with a magnetron sputtering apparatus. The second substrate after the film formation showed a transmittance, measured within a wavelength region of 350 to 1,100 nm, of 5% or less, exhibiting a total reflection state.

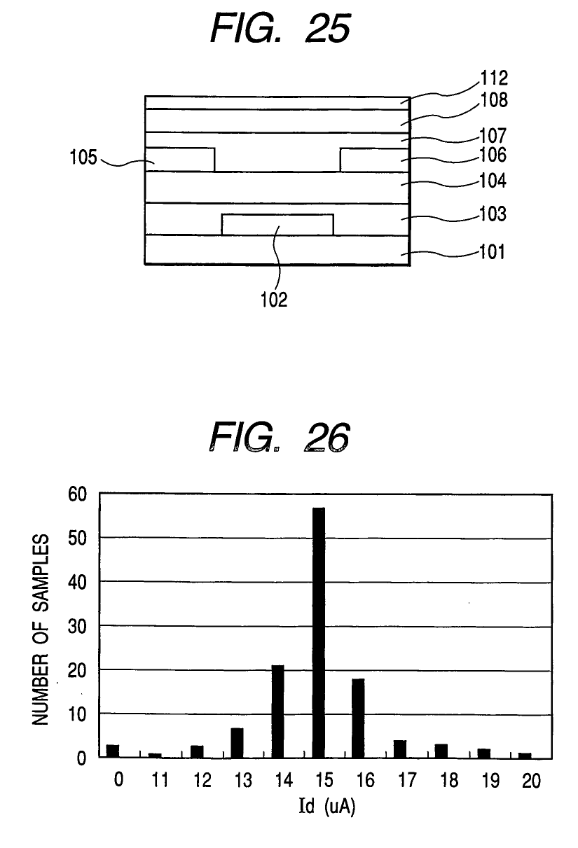

A thin film transistor element was prepared in the same manner as in Example 1. As shown in a schematic cross-sectional view in FIG. 25, and in contrast to Example 1 shown in FIG. 1, an Al light-shielding film (112 in FIG. 25) was added. Static characteristics were measured with a semiconductor parameter analyzer. FIG. 26 is a chart showing a fluctuation in the drain current Id in a state that a source voltage; a drain voltage and a gate voltage respectively of 0 V, −20 V and −20 V are applied to an element of a gate length of 80 μm and a gate width of 5 mm. The chart shows a form close to the normal distribution curve with the half-width being narrow. Also the elements showing Id=0 by destruction were satisfactorily less than 10.

### Comparative Example 5

On the other hand, as a comparative example, an element was prepared through all the same steps except that the protective film was not provided, and evaluation was made on the DC characteristics of the transistor element. As a result, many elements present on one substrate were broken, and the transistor characteristics showed significant fluctuation.

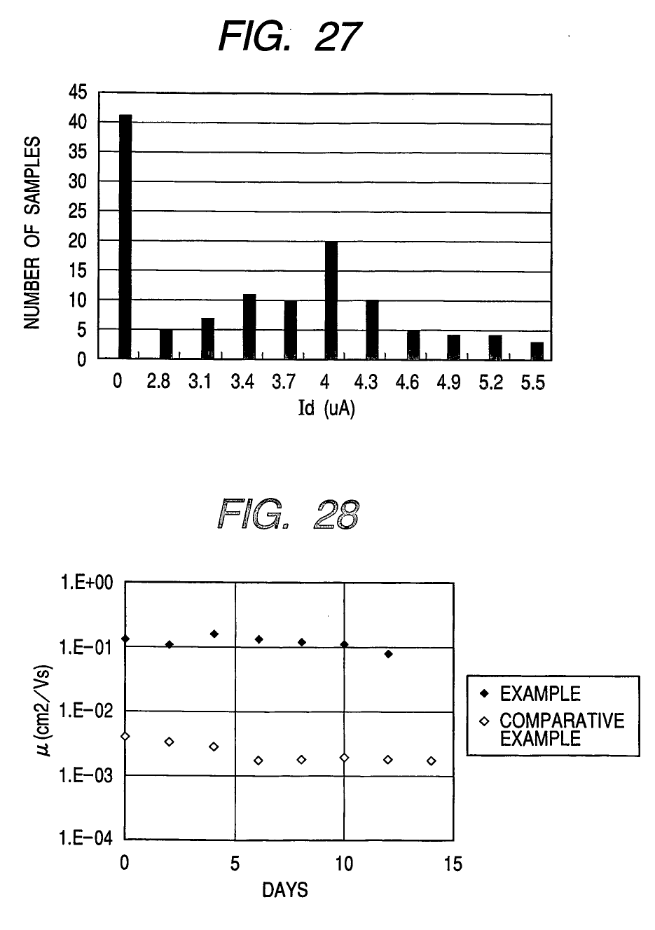

FIG. 27 is a chart showing a fluctuation of the drain current Id measured in the same manner as in Example 5 shown in FIG. 26. While the element size is the same as in Example, the drain current is about ¼. Also the half-width is wider, indicating a larger fluctuation. Also it can be observed that nearly half of the elements show Id=0 due to element destruction.

FIG. 28 is a chart showing a change over time of the mobility measured on one element in each of the Example and Comparative Example. The storage environment is the air of 25° C. and 45%. The element of the Comparative Example showed a mobility lower by about one digit than the element of the Example. Based on the fact that the satisfactory transistor characteristics were obtained, it was confirmed that the organic semiconductor film was not exposed to the air and the sealing was effective.

### Example 6

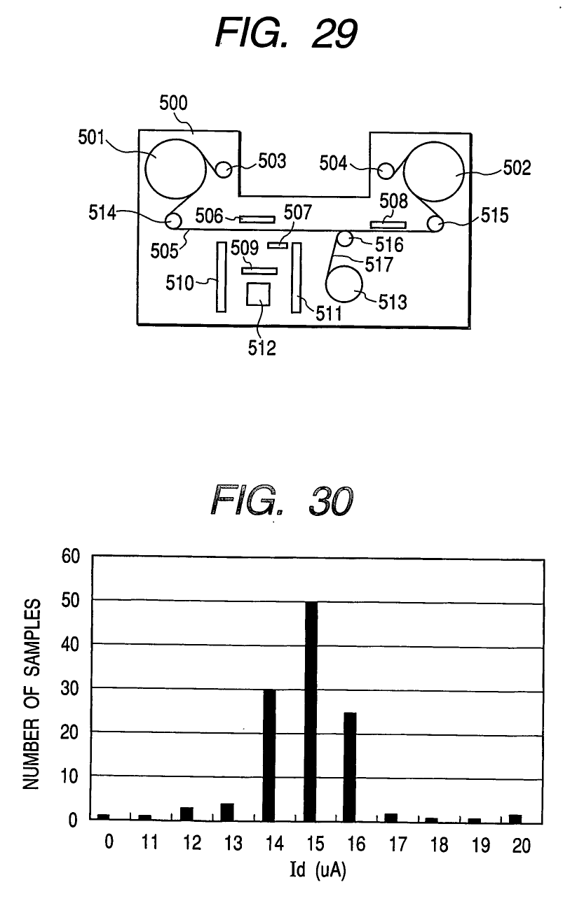

FIG. 29 is a schematic view of a manufacturing apparatus for executing the protective film forming process of the present invention in an in-line mode. In this apparatus, lamination is executed by a laminating heater, but a thermal fusion is not essential in the present invention. In FIG. 29, 500 denotes a vacuum chamber; 501, an unwinding roll; 502, a winding roll; 503, an interleaf unwinding roll; 504, an interleaf winding roll; 505, a first substrate having been subjected up to a step shown in FIG. 8; 506, a substrate heater; 507, a film thickness monitor; 508, a laminating heater; 509, a film forming shutter; 510 and 511, deposition preventing plates; 512, an evaporation source; 513, a second substrate unwinding roll; 514 and 515, tension rollers; 516, a second substrate laminating roller; and 517, a second substrate.

The vacuum chamber 500 is maintained at a pressure lower than the atmospheric pressure through an evacuating pump and a valve (not shown in the drawing), and the first substrate 505 having been subjected up to the step shown in FIG. 8 is transported at a constant speed from the unwinding roll 501 to the winding roll 502. The tension rollers 514, 515 regulate the tension of the first substrate. An interleaf for preventing scratches on the substrate surface is wound up by the interleaf winding roller 503.

The substrate passes through a gate valve (not shown in the drawing) in the vacuum chamber 500 and is introduced into a film forming space covered with the deposition preventing plates 510, 511. The film forming space is maintained in a vacuum degree of 2×10⁻⁴ Pa, and the shutter 509 is opened at suitable timing as needed, whereby particles of an organic semiconductor generated from the evaporation source 512 are deposited on the first substrate. At the film formation, the substrate heater 506 is turned on to control the substrate at a desired temperature. A film formation was executed with pentacene. The evaporation was managed by the film thickness monitor, and an evaporation rate of 0.9 Å/sec. and a substrate temperature of 50° were employed. The formed pentacene film had a total thickness of 70 nm.

Then the substrate 505, after the formation of the organic semiconductor film, passes by the laminating heater 508, then passes through the laminating roller 516 along with the second substrate 517 supplied from the second substrate unwinding roller 513 and is pressed thereto. The two substrates are fusion-bonded by heat of the laminating heater. The first and second substrates after fusion-bonding are finally wound up on the winding roller 502 along with an interleaf supplied from the interleaf unwinding roller 504 prior to winding, whereupon the process is terminated. In this process, the organic semiconductor film is not brought into contact with the air at all, does not involve the air during the lamination and can be smoothly forwarded to a mounting process.

### Example 7

An organic thin film transistor was prepared with the same configuration as in Example 1 except that a light-shielding pliable substance was employed, and evaluation was made on the transistor characteristics after superposition in the presence and absence of the protective film. The second substrate was composed of a polyethylene-polyester-EVA film with a thickness of 150 μm. Apiezon grease was employed as the light-shielding pliable substance. Differently from a milk-white silicone-based grease, the Apiezon grease is a black-colored hydrocarbon-based grease and has light-shielding properties.

A thin film transistor element was prepared in the same manner as in Example 1. Static characteristics were measured with a semiconductor parameter analyzer. FIG. 30 is a chart showing a fluctuation in the drain current Id in a state that a source voltage, a drain voltage and a gate voltage respectively of 0 V, −20 V and −20 V are applied to an element of a gate length of 80 μm and a gate width of 5 mm. The chart shows a form close to the normal distribution curve with the half-width being narrow. Also the elements showing Id=0 by destruction were satisfactorily less than 10.

### Comparative Example 6

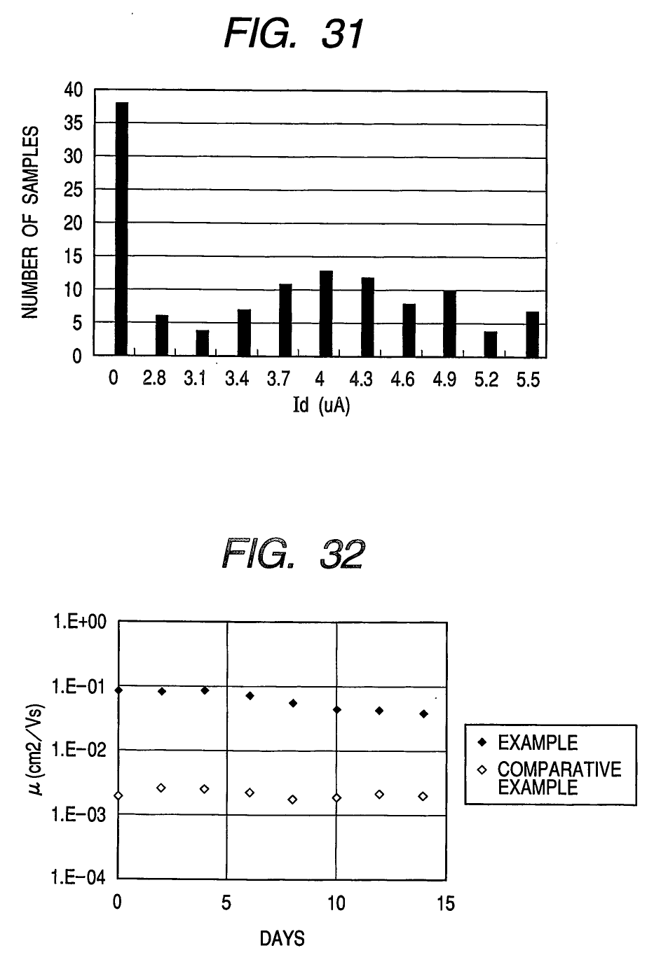

On the other hand, as a comparative example, an element was prepared through all the same steps except that the protective film was not provided, and the DC characteristics of the transistor element were evaluated. As a result, many elements present on one substrate were broken, and the transistor characteristics showed significant fluctuation. FIG. 31 is a chart showing a fluctuation of the drain current Id measured in the same manner as in the Example shown in FIG. 30. While the element size is the same as in the Example, the drain current is about ¼. Also the half-width is wider, indicating a larger fluctuation. In addition, it can be observed that nearly half of the elements show Id=0 by element destruction.

FIG. 32 is a chart showing a change over time of the mobility measured for one element in each of the Example and Comparative Example. The storage environment is the air of 25° C. and 45%. The element of Comparative Example showed a mobility lower by about one digit than the element of the Example. Based on the fact that the satisfactory transistor characteristics were obtained, it was confirmed that the organic semiconductor film was not exposed to the air and the sealing was effective.

The present invention has been explained based on the structure shown in FIG. 1, but is applicable not only to such structure. Those skilled in the art would easily understand that the technical idea of the present invention can be applied to cases bearing the same technical subject. It would also be easy for those skilled in the art to understand that many parts not directly related to the invention, such as a field insulation film or protective film or a contact via, were omitted.

The present invention is not limited to the above embodiments, and various changes and modifications can be made within the spirit and scope of the present invention. Therefore, to apprise the public of the scope of the present invention, the following claims are made.

1. An organic thin film transistor utilizing an organic semiconductor film, comprising a first substrate, a gate electrode, a gate insulation film, an organic semiconductor film, a source electrode, a drain electrode, a protective film and a second substrate.

2. An organic thin film transistor according to claim 1, wherein said protective film comprises a pliable substance.

3. An organic thin film transistor according to claim 1, wherein at least a part of said protective film comprises a pliable substance having a consistency within a range from 200 to 700.

4. An organic thin film transistor according to claim 1, wherein said protective film comprises a pliable substance and an insulation film.

5. An organic thin film transistor according to claim 1, wherein said protective film comprises a pliable substance and a light-shielding film.

6. An organic thin film transistor according to claim 1, wherein said protective film is formed from a mixture containing a pliable substance and a hygroscopic material.

7. An organic thin film transistor according to claim 1, wherein said pliable substance is a vacuum grease.

8. An organic thin film transistor according to claim 1, wherein said hygroscopic material comprises calcium carbonate.

9. A method for producing an organic thin film transistor comprising a first substrate, a gate electrode, a gate insulation film, an organic semiconductor film, a source electrode, a drain electrode, a protective film and a second substrate, the method comprising:
forming a gate electrode, a gate insulation film, an organic semiconductor film, a source electrode, and a drain electrode on a first substrate,
forming a protective film on a second substrate, and
superposing a surface, bearing the organic semiconductor film, of the first substrate upon a surface, bearing the protective film, of the second substrate.

10. A method for producing an organic thin film transistor according to claim 9, wherein said protective film comprises a pliable substance.

11. A method for producing an organic thin film transistor according to claim 9, wherein at least a part of said protective film comprises a pliable substance having a consistency within a range from 200 to 700.

12. A method for producing an organic thin film transistor according to claim 9, wherein at least one of said source electrode and said drain electrode is formed by printing technology.

13. An apparatus for producing an organic thin film transistor utilizing an organic semiconductor film, which superposes a protective film by a producing method according to claim 9, wherein a step of forming the organic semiconductor film and a step of superposing the protective film are successively carried out in the same apparatus.
